(19) United States
(12) Patent Application Publication
(10) Pub. No.: US 2024/0288319 A1
(43) Pub. Date: Aug. 29, 2024

(54) METHOD OF MEASURING THE JUNCTION TEMPERATURE OF A SEMICONDUCTOR DEVICE

(71) Applicant: Siemens Industry Software Inc., Plano, TX (US)

(72) Inventors: Gabor Farkas, Budapest (HU); Zoltan Sarkany, Budapest (HU)

(21) Appl. No.: 18/681,795

(22) PCT Filed: Aug. 31, 2021
(86) PCT No.: PCT/US2021/048448

§ 371 Date: Feb. 6, 2024

(51) Int. Cl. G01K 7/01; H03K 17/687

(52) U.S. Cl. CPC G01K 7/01; H03K 17/687

(57) ABSTRACT

A method of measuring the junction temperature, Tⱼ, of a semiconductor switching element in real-time, and a device for carrying out such a measurement are described. A plurality of measurements of a first and a second, different, temperature-sensitive parameter (TSP) of the semiconductor switching element while recording other quantities determining the semiconductor switching element operating point is taken. The junction temperature value based on the measured values of the first temperature-sensitive parameter and the at least one second temperature-sensitive parameter are calculated and compared to determine the actual junction temperature Tⱼ. Each of the plurality of measurements of the first temperature-sensitive parameter and the at least one second temperature-sensitive parameter is synchronized with a switching event of the semiconductor switching element.

The present patent document is a § 371 nationalization of PCT Application Serial No. PCT/US2021/048448, filed Aug. 31, 2021, designating the United States, which is incorporated by reference in its entirety.

### TECHNICAL FIELD

The present disclosure relates to a method of measuring the junction temperature of a semiconductor device, in particular, a semiconductor device used in a power switching application.

### BACKGROUND

The growing power density of power electronics apparatus has led to the temperature of semiconductor power components contained in such apparatus as being the primary root cause of reliability issues. These may lead to limited lifetime and early equipment failure, as well as inconsistent performance. While models may be used to enable predictive and preventative maintenance schemes, these models rely on valid and accurate input data.

The thin active heat generating layer on the surface of a semiconductor chip is customarily called a junction, and its temperature is denoted as Tⱼ. This temperature and its transient change is the critical factor for the operability and lifetime of semiconductor components. Recording Tⱼ during real time operation is a challenging engineering problem, but important for a more accurate tracking of device ageing and preventing possible breakdown.

This issue is particularly acute in power switching applications, where the broad range of applications in which semiconductor elements are used creates a multitude of measurement requirements. Switching elements may be grouped in applications, such as according to voltage and current rating or switching frequency. For example, the switching elements employed in engine control units for car engines and locomotives may have a switching frequency of hundreds of Hertz, but switching elements used in power conversion, such as DC/DC and AC/DC conversion applications, will have a switching frequency of several thousand Hertz. The switching elements may include different semiconductor devices, such as super junction MOSFETs, IGBTs, wide bandgap material MOSFETs manufactured on silicon carbide substrate, and gallium nitride HEMT devices. Consequently, a one-size-fits-all measurement solution is almost impossible to produce, as each Tⱼ junction temperature measurement requires the monitoring of different physical parameters, requiring a variety of instrumentation and testing methodologies.

Another issue is that to obtain valid measurement data, to implement predictive maintenance schemes, or to understand failure modes, data may be obtained from the switching element in actual use. However, data may be obtained using specific testing environments that attempt to replicate the operating conditions the switching element will face in use. Established test bench systems track temperature change in tests at low switching frequencies, with exemplary switching period times in the order of 0.1 to 1000 seconds. In this switching domain, the power dissipation is due mainly to the conduction loss of the switching element in its “on” state. This operation mode induces failure mechanisms that may differ significantly from those encountered when the switching element is in actual use. Therefore, mainstream measurement techniques currently available on the market at the time of filing are effectively differing workarounds to the problem of not being able to measure the junction temperature Tⱼ directly. Such techniques rely instead on attempting to measure the junction temperature Tⱼ of a switching element indirectly.

External sensors located in accessible positions may be used to measure temperature during operation of the switching element, but easily accessible positions may not be in the main heat conduction path. As a result, a distorted and potentially inadequate picture of the health of power switching apparatus is obtained. Larger power switching modules may integrate temperature sensors onto a base plate, but these will yield a temperature that is systematically lower than the actual junction temperature Tⱼ. Alternatively, attempts may be made to include temperature sensors in the switching element itself by integrating sensors on the dissipating semiconductor device layer. However, this leads to a prohibitive increase in device cost due to the requirements of special packaging and dedicated readout electronics integrated into the device. Consequently, none of these are attractive solutions for mass market applications.

Another approach, instead of direct measurements, is to rely on calculations, using alternative thermal or electrical parameters. These derive the temperature of the hottest point from the equivalent one dimensional thermal resistance-capacitance model of the heat conducting path from the junction towards the point which is accessible for temperature measurement. This is done using the average power measured on the device and from external sensor temperature. The equivalent thermal resistance-capacitance model is that the values used are themselves based on simulations or partially on measurements of selected samples. Calculated temperatures may differ significantly to actual temperatures in an actual real module or packaged discrete device.

The heat conduction path may vary during the lifetime of apparatus because wear, degradation, mounting delamination, and soldering issues may occur. The outcome of such effects cannot be monitored accurately because the model steadily converts monitoring point temperatures to junction temperatures Tⱼ. Existing methodologies therefore suffer from a number of drawbacks, all of which are related to the estimation of the semiconductor junction temperature Tⱼ from farther points in real-life systems.

The lack of accurate methodologies for directly measuring the junction temperature Tⱼ in a system operating at realistic frequencies is an issue for the successful utilization of semiconductor switching elements.

In all attempts for measuring Tⱼ, the temperature measurement is based on the recording of a temperature sensitive electric parameter of the semiconductor device, e.g., referred to as TSP. These parameters depend not only on the junction temperature, but also on all variables defining the operating point of the device, such as voltages across device pins and currents through the device. Existing attempts focus on the use of a single TSP, mainly in test systems working at continuous powering or switching at low frequencies. Attempts to introduce a multitude of TSPs do not take the interrelation and correlation of those into consideration.

For determining the junction temperature with a proper accuracy, the temperature dependence of any temperature-dependent parameters should be calibrated. The calibration process is a determination of a valid mapping between the temperature to be recorded and the semiconductor device parameter actually measured, at one or several sets of influencing variables such as device voltages and currents.

The temperature dependence of the temperature-sensitive electrical parameters may be lower than their dependence on other variables. In former applications, recognizing that a single temperature sensitive electrical parameter is influenced by the deterioration of a device this non-thermal change has been used only as a stop criterion in reliability testing.

### SUMMARY

The scope of the present disclosure is defined solely by the appended claims and is not affected to any degree by the statements within this summary. The present embodiments may obviate one or more of the drawbacks or limitations in the related art.

The present disclosure aims to address the above issues by providing, in a first aspect, a method of measuring the junction temperature, Tⱼ, of a semiconductor switching element in real-time. The method includes: a) taking a plurality of measurements of a first temperature-sensitive parameter (TSP) of the semiconductor switching element while recording other quantities determining the semiconductor switching element operating point; b) taking a plurality of measurements of at least a second temperature-sensitive parameter of the semiconductor switching element while recording other quantities determining the semiconductor switching element operating point, wherein the second temperature-sensitive parameter is different to the first; c) calculating a junction temperature value based on the measured values of the first temperature-sensitive parameter and the at least one second temperature-sensitive parameter; and d) comparing the first and at least one second calculated junction temperature values to determine the actual junction temperature Tⱼ, wherein each of the plurality of measurements of the first temperature-sensitive parameter and the at least one second temperature-sensitive parameter is synchronized with a switching event of the semiconductor switching element.

By measuring at least two independent temperature-sensitive parameters and synchronizing these measurements to the switching event itself, the semiconductor junction temperature Tⱼ may be determined accurately, directly from real-life measurements. Possible wear or degradation effects influencing one temperature-sensitive parameter but affecting another parameter to a different extent may be identified and treated. Effects due to transient or other events not linked to the switching behavior of the semiconductor switching element are minimized. The measurement of each temperature-sensitive parameter is optimized for the individual parameter itself, including the synchronization delay to the switching event and the duration of the time slot measurements are taken in.

The second temperature-sensitive parameter may be independent of the first temperature-sensitive parameter.

In one embodiment, act c) may include: correlating the measured values of the first temperature-sensitive parameter and correlating the measured values of the at least one second temperature-sensitive parameter to determine a single value of each of the first and at least one second temperature-sensitive parameters; and determining the first and at least one second initial junction temperatures from these single values of each of the first and at least one second temperature-sensitive parameters.

Alternatively, act c) includes determining a value of a junction temperature Tⱼ from each of the measured values of the first temperature-sensitive parameter and the at least one second temperature-sensitive parameter; and correlating the determined values of Tⱼ to obtain a first initial junction temperature Tⱼ and at least a second initial junction temperature Tⱼ.

The first temperature-sensitive parameter may be measured against the first variable in a first dedicated time slot, and the at least one second temperature-sensitive parameter may be measured in a second dedicated time slot.

Each dedicated time slot may be determined by the optimum time for measuring a temperature-sensitive parameter after the switching event.

The duration of each dedicated time slot may be determined by the behavior of the temperature-sensitive parameter after a switching event occurs.

All of the above embodiments may be extended systematically to any higher n number of temperature-sensitive parameters. The method may further include calibrating the first temperature-sensitive parameter and calibrating the second temperature-sensitive parameter. Also, the calibrating may take place either in a thermostatic environment separate to the real-time measurement or using additional sensors during the real-time measurement. Alternatively, calibrating either the first or the at least one second temperature-sensitive parameter by reference to the other available parameters during the real-time measurement.

The temperature-sensitive semiconductor parameters may be determined at switching transients and include the level, timing, or waveform of a gate voltage or other input pin voltage. Alternatively, the temperature-sensitive semiconductor parameters are determined at switching transients and include the level, timing, or waveform of the input current of a transistor or p-n junction type control pin device. Further alternatively, the temperature-sensitive semiconductor parameters are determined at the conduction phase of a switching operation, and include the level, timing, or waveform of the drain or collector voltage of semiconductor devices in the conduction period of switching. Yet further alternatively, the temperature-sensitive semiconductor parameters include characteristic switching times.

The first and at least one second temperature-sensitive parameters may be measured at operational voltage and current.

A set of a plurality of different temperature-sensitive parameters may be used to determine the semiconductor junction temperature of the semiconductor switching element.

In a second aspect, the present disclosure provides a device configured to measure the junction temperature, Tⱼ, of a semiconductor switching element in real-time. The device includes: a first data acquisition unit configured to measure a first temperature-sensitive parameter of a semiconductor switching element; at least a second data acquisition unit configured to measure at least a second temperature-dependent parameter of a semiconductor switching element; and a processing unit configured to receive inputs from the first and at least one second data acquisition units further inputs indicating the auxiliary temperature, current, and voltage of the semiconductor switching element and to determine a value of the junction temperature Tⱼ using the method described above.

### BRIEF DESCRIPTION OF THE DRAWINGS

The present disclosure is now described by way of example only, and with reference to the accompanying drawings.

FIG. 1 is an example of a simplified circuit diagram of a MOSFET device in a switching application with control, load, and relevant parasitic elements.

FIG. 2 illustrates an example of voltage, V, and current, I, waveforms at the OFF/ON and ON/OFF switching transient of the MOSFET device in FIG. 1.

FIG. 3 illustrates an example of bilinear calibration mapping for channel resistance (R_{DSON}) of a MOSFET device, as a function of the Tⱼ junction temperature and the drain current I_{D} as another variable.

FIG. 4 illustrates a schematic diagram of a device to measure the junction temperature Tⱼ of a semiconductor switching element in accordance with an embodiment.

FIG. 5 is a flow chart illustrating a method of measuring the junction temperature Tⱼ of a semiconductor switching element in real-time in accordance with an embodiment.

FIG. 6 is an example of a schematic diagram showing the relationship between individual time slots and the switching events SE.

FIG. 7 is an example of a schematic illustration of measurements within a time slot highlighted from FIG. 6.

### DETAILED DESCRIPTION

As outlined above, the parameters measured to determine the junction temperature Tⱼ vary with other characteristic quantities, such as drain current, voltage on the gate, source and drain pins and device capacitances, all of which cause transient changes affecting the measurements made. In addition, there may be issues arising from the external load defining the operation point of the semiconductor switching element and the time variant change of this load. The embodiments of the present disclosure deal with these issues by using the synchronous measurement of two or more temperature-sensitive parameters. These temperature sensitive electrical parameters or time intervals or durations include, but are not limited to: (1) level, timing, or waveform of the gate voltage or other input pin voltage in MOSFET, IGBT, or other semiconductor devices at switching transients; (2) level, timing, or waveform of the input current in bipolar transistors, junction FET, HEMT devices or other devices with p-n junction type control pin at switching transients; (3) level, timing, or waveform of drain or collector voltage of semiconductor devices in the conduction period of the switching event; or (4) switching times and other temperature-dependent parameters.

The temperature-sensitive parameters may be measured, but not exclusively, at the operational voltage and current levels belong to the regular functioning of the device in which the semiconductor switching element resides. In addition, where a semiconductor switching element exhibits a regular, periodic operation, the temperature-sensitive parameters may be measured, but not exclusively, on a fixed time grid synchronized to the switching time of the device in which the semiconductor switching element resides. This may therefore result in a series of discrete measurements rather than a single continuous measurement of a temperature-sensitive parameter.

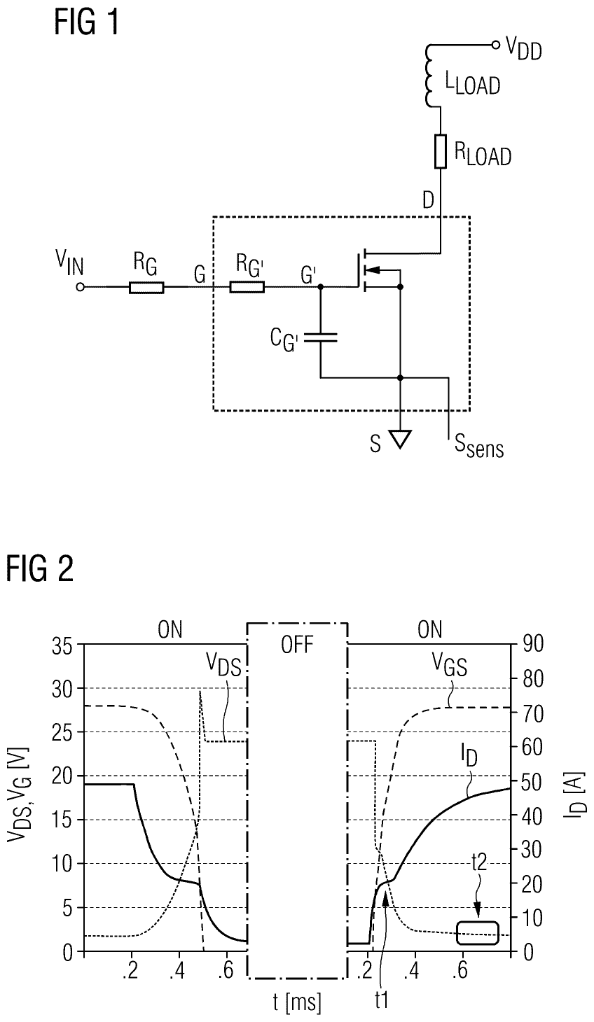

FIG. 1 is a simplified circuit diagram of an example of a MOSFET device in a switching application with control, load, and parasitic elements. The MOSFET includes source S, gate G, and drain D terminals, with associated resistance, capacitance, and inductance (e.g., external gate resistance R_{G}, internal gate resistance R_{G}′, load R_{LOAD}, internal gate capacitance C_{G}′, and load inductance L_{LOAD}). FIG. 2 illustrates the drain voltage, V_{DS}, gate voltage, V_{GS}, and current, I_{D} waveforms at the OFF/ON and ON/OFF switching transient of the MOSFET device in FIG. 1. The parasitic elements affect the waveforms as indicated in the voltage waveforms V_{GS}, V_{DS}, with the current waveforms I_{D}. V_{GS} shows an approximate exponential drop from a plateau value in the OFF/ON switching transient and an approximate exponential growth over time to the same plateau value in the ON/OFF switching transient. In addition, two possible temperature-sensitive parameters are illustrated: the Miller plateau at t₁ in the V_{GS} gate voltage and the low Vas drain voltage at t₂ in the “on” state.

In order to provide a direct measurement of the junction temperature Tⱼ, the embodiments take advantage of the behavior of the semiconductor switching element around the switching event. For each temperature-sensitive parameter, a measurement interval may be defined, synchronized to the switching event and within a time slot where perturbations caused by the switching event itself are minimal. By measuring the temperature-sensitive parameter within a time slot determined by the measurement interval, a direct measurement of Tⱼ may be made. Taking the Miller plateau of V_{GS} at t₁ shown in FIG. 2, this occurs several hundred nanoseconds after the switching event, allowing a measurement time slot to be defined. The low V_{DS} drain voltage occurs after several milliseconds and continues for several microseconds, again allowing a measurement time slot to be defined around t₂. The duration of the time slot is initially determined by the time duration of the temperature-sensitive parameter being measured. For the Miller plateau, less than 2 microseconds may be required, but for the low Vas voltage, this may be greater than 5 milliseconds. However, as discussed below in greater detail, several other factors may also influence the duration of the time slot. Within the time slot, many measurements of the temperature-sensitive parameter may be taken. Various techniques used to reduce noise and improve signal processing may be used, such as taking a moving average, a weighted average, or using mathematical treatments such as a Kalman filter.

In order to determine the junction temperature Tⱼ, the temperature dependence of the temperature-sensitive parameter may be calibrated, setting a valid mapping between the temperature to be recorded and the semiconductor switching element temperature-sensitive parameter being measured. If an approximately linear temperature to parameter mapping exists, the characteristic slope of the mapping function may be referred to as the “sensitivity” of the temperature-sensitive parameter. This may also be extended to mapping where the temperature-sensitive parameter is also dependent upon additional quantities, variables beyond temperature, or where the mapping function is non-linear. Calibration of a single variable results in a temperature to temperature-sensitive parameter mapping function curve that is linear, polynomial, exponential or some other function of the form y=m·f(x)+c, where f(x) denotes that y is some function of x.

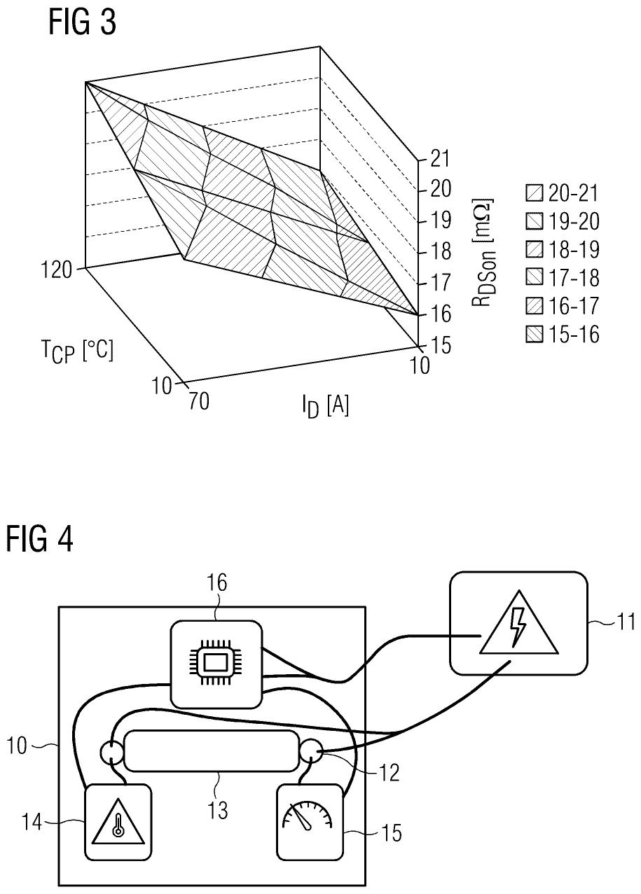

FIG. 3 illustrates the bilinear calibration mapping for the channel resistance (R_{DSON}) of a MOSFET device. The channel resistance (z-axis, [mΩ]) is dependent on both junction temperature (T_{CP} [° C.], y-axis) and drain current (I_{D} [A], x-axis), and the mapping function shows a flat surface wherein the channel resistance has a linear relationship with both the temperature and the current. Curved calibration surfaces may be equally constructed.

Calibration may occur either before or after starting the measurements on the live semiconductor switching element, device, or system containing the semiconductor switching element. In addition, it may become necessary to calibrate the semiconductor switching element during measurement if, for example, the values of Tⱼ obtained from the at least two temperature-sensitive parameters under evaluation begin to diverge. Taking the example of calibration before starting measurements on the live system, the calibration process is carried out whilst keeping the semiconductor switching element, device, or system in a thermostated environment or in a live environment with additional appropriate calibrated temperature sensors. These additional sensors may be dedicated to the calibration and testing process or may reside on other components within the semiconductor switching element system and are calibrated in advance of the calibration and testing processes. Calibration itself may be carried out using a longer dwelling time at a particular temperature or as a sweep through a series of different temperatures. If no separate temperature sensors are used, the calibration process may be based on the measured environment temperature. Calibration may also be carried out using one or more variables, for example, by calibrating temperature at a fixed device operating point, calibration on two variables, such as temperature and device current, calibration on three variables, such as temperature, device current, and device voltage, or more variables if desired.

Calibration may take place on multiple variables such as temperature, current, and voltage in a powered state of the semiconductor switching element, device, or system, as determined by the available mapping. In the powered state, the junction temperature Tⱼ differs considerably from the setpoint of the thermostated environment. Therefore, calibration also requires an additional back tracing act, stepping from the powered state determined by the operational quantities to a different power level, as specified in the calibration processes of the JDEC JESD51 and IEC/EN 60747 standards. In addition, the calibration methodology may be improved by incorporating known semiconductor device characteristics and analytical modelling techniques, such as Gummel-Poon, Schichmann-Hodges, and high-level Spice models. Rather than using a calibration that fits a multidimensional surface onto a set of influencing factors, the analytic equations may be used as the initial approach and their parameters tuned during calibration. This is particularly useful to cater for unforeseen circumstances in which the operation point of the semiconductor switching element is not covered by the original calibration range.

As mentioned above, it may be necessary to perform additional recalibration acts during the determination of the junction temperature Tⱼ, when the values of Tⱼ yielded by the synchronous measurement of two temperature-sensitive parameters start to diverge. Such recalibration may be carried out in dedicated time slots in the measurement process outlined below, enabling the measurement process to continue without interruption. The operating point of the semiconductor switching element, device, or system may be altered, for example, by applying a predefined constant current rather than the operational current. Alternatively, or additionally, the timing of measurements in the appropriate time slots may be altered for example, by increasing the external gate resistance R_{G}, because the longer measurement time may be used to obtain a more precise measurement of Tⱼ with better noise suppression than possible during the conventional measurement time. Such recalibration will result in all of the temperature-sensitive parameters being recalibrated simultaneously. If recalibration of only a single temperature-sensitive parameter is desired, then this may be done by a using separate dedicated time slot inserted solely for the recalibration. Because these additional time slots are inserted into the existing measurement process and make up a very small fraction of the total number of time slots, the live operation of the semiconductor switching element, device or system remains unaltered, without any perturbation or malfunction.

The method by which the simultaneous measurement of at least two temperature-sensitive parameters is carried out in embodiments are now discussed in more detail. The measurements may occur in any of the following: live functional systems; experimental mock-ups of live systems; dedicated test apparatus analyzing semiconductor switching element characteristics or the operation of a device or system containing the semiconductor switching element; or dedicated test apparatus analyzing the semiconductor switching element, device or systems wear, deterioration, reliability, or lifetime.

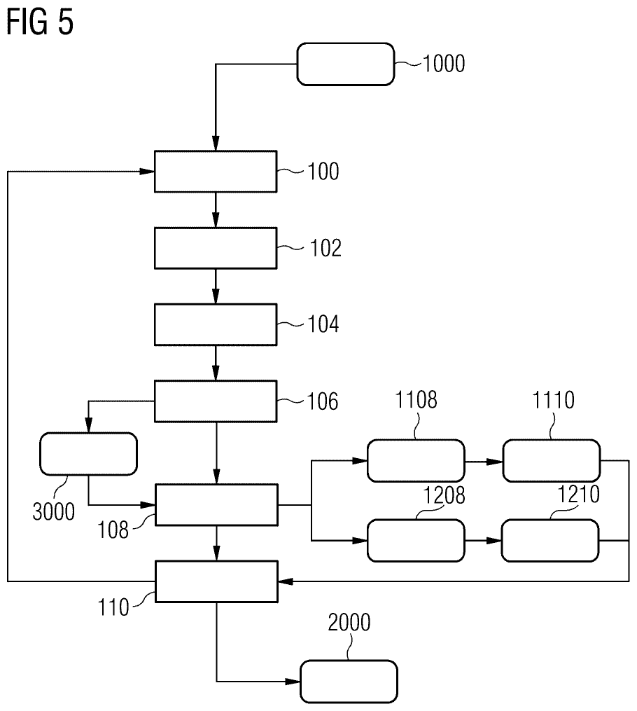

In particular, a device configured to measure the junction temperature, Tⱼ, of a semiconductor switching element in real-time includes several elements. FIG. 4 illustrates a schematic diagram of a device to measure the junction temperature Tⱼ of a semiconductor switching element in accordance with an embodiment. In FIG. 4, unit 10 represents the system which hosts the power switching element. It may be a live functional system as a vehicle in motion, or a mock-up of a real system or a dedicated test equipment/measurement system. The unit 10 is connected to a power source 11, which in the embodiment illustrated is remote from the unit 10. However, depending on the application and/or environment in which the unit 10 is used in, the power source 11 may be contained within the device itself as a component. The unit 10 also includes connectors 12 for connecting to a semiconductor switching element 13, such as the MOSFET illustrated in FIG. 1. In order to measure the temperature-sensitive parameters required to determine the semiconductor junction temperature Tⱼ, the unit 10 includes a first data acquisition channel 14 which records a first temperature-sensitive parameter of the semiconductor switching element 13, and at least a second data acquisition channel 15 configured to measure at least a second temperature-dependent parameter of a semiconductor switching element 13. The unit 10 may include additional external temperature sensors, voltage measuring devices, and current measuring devices. Should more than two temperature-sensitive parameters be measured, additional data acquisition channels are provided (note shown). A processing system 16 configured to receive inputs from the first 14 and at least one second 15 channels and further inputs indicating other quantities such as the temperature at other locations and the current and voltage of the semiconductor switching element 13 is also provided. The processor 16 is also configured to determine a value of the junction temperature Tⱼ using the method described below with reference to FIG. 5. Although, in the illustrated embodiment, the processor forms part of the measurement device 10, the processor 16 may be located remote from the other components of the measurement device 10. Optionally, a control unit determining voltages and currents in the system hosting the semiconductor switching element and a control unit determining the temperature of the thermal environment around the system may be included (not shown).

FIG. 5 is a flow chart illustrating a method of measuring the junction temperature Tⱼ of a semiconductor switching element in real-time in accordance with an embodiment. The measurement results in a direct measurement of the semiconductor switching element junction temperature Tⱼ in real life or in dedicated test systems. The method 100 includes act 102 of taking a plurality of measurements of a first temperature-sensitive parameter of the semiconductor switching element. In the example device of FIG. 1, this would involve taking measurements of the Miller plateau of the V_{GS} gate voltage at t₁.

At act 104, a plurality of measurements of at least a second temperature-sensitive parameter of the semiconductor switching element are taken. The second temperature sensitive-parameter is different to the first temperature-sensitive parameter. For example, the first temperature-sensitive parameter may be the level of the gate voltage and the second temperature-sensitive parameter may be the waveform of the drain voltage for a MOSFET under test. Similarly, for the example of FIG. 1, this would involve measuring the low V_{DS} drain voltage at t₂. In all measurements of a number of other quantities that determine the semiconductor switching element operating point, such as external temperature, switching element voltage and current are also recorded.

Act 106 involves determining a first initial junction temperature Tⱼ based on the measured values of the first temperature-sensitive parameter, where Tⱼ is the highest operating temperature of the semiconductor switching element.

Act 108 does the same for the second temperature-sensitive parameter, such that at least a second initial junction temperature Tⱼ based on the measured values of the at least one second temperature-sensitive parameter is determined.

At act 110, the first and at least one second initial junction temperatures Tⱼ are compared to determine the junction temperature Tⱼ. In order to provide an accurate derivation of the junction temperature Tⱼ, each of the plurality of measurements of the first temperature-sensitive parameter and the at least one second temperature-sensitive parameter is synchronized with a switching event of the semiconductor switching element.

Act 108 may be carried out in two different ways. Firstly, at act 1108, the measured values of the first temperature-sensitive parameter are correlated and the measured values of the at least one second temperature-sensitive parameter are also correlated. This enables a determination of a single value of each of the first and at least one second temperature-sensitive parameters. At act 1110, the first and at least one second initial junction temperatures are determined from these single values of each of the first and at least one second temperature-sensitive parameters. These are then compared in act 110 as before.

Alternatively, at act 1208, a value of a junction temperature Tⱼ is determined from each of the measured values of the first temperature-sensitive parameter and the at least one second temperature-sensitive parameter. These are then correlated at act 1210 to obtain a first initial junction temperature Tⱼ and at least a second initial junction temperature Tⱼ. These are then compared in act 110 as before.

As discussed above, each temperature-sensitive parameter is measured in a time slot that is synchronized with the semiconductor switching element switching event at its optimum measurement time. For example, as shown in FIG. 1, the Miller plateau is measured at t₁ time just after some tens of nanoseconds from switching event, the low V_{DS} drain voltage is measured for a time of several milliseconds with a t₂ delay in the millisecond range. As a basic rule, the duration of a time slot is determined by the duration of the temperature-sensitive parameter, after transient perturbations decay. Noise or other transient effects may affect the quality of the measurement, and therefore it may be advantageous to extend the time slot duration to decrease these effects. Within the time slot itself it may be desirable to take continuous measurements of the temperature-sensitive parameter, or to take repeated sample measurements at pre-determined intervals, depending on the behavior of the temperature-sensitive parameter.

As discussed above, calibration improves the accurate measurement of the junction temperature Tⱼ. Calibration may take place either before the measuring or after the measuring. The process as shown in acts 1000 and 2000 in FIG. 5 involves calibrating the first temperature-sensitive parameter and at least a second temperature-sensitive parameter in relevant operating points. The calibrating may take place either in a thermostatic environment separate to the real-time measurement or using additional sensors during the real-time measurement. As an alternative to using additional sensors, it is also possible to calibrate either the first or the at least one second temperature-sensitive parameter by reference to the other of the at least one second or first temperature-sensitive parameters during the real-time measurement. With this option, and with that involving additional sensors, calibration occurs during real-time measurements by allocating specific time slots during the measurement process for calibration. This is illustrated at act 3000, where an additional time slot is inserted into the measurement cycle. As outlined above, these additional recalibration acts are required during the determination of the junction temperature Tⱼ, when the values of Tⱼ yielded by the synchronous measurement of two temperature-sensitive parameters start to diverge. Although FIG. 5 illustrates the use of two different temperature-sensitive parameters to determine the semiconductor junction temperature Tⱼ this should not be taken to be limiting. A minimum of two temperature-sensitive parameters. TSP1, TSP2, is required to determine the semiconductor junction temperature Tj by comparison of the separately obtained semiconductor junction temperatures Tⱼ1, Tⱼ2. Therefore, a set of a plurality of different temperature-sensitive parameters TSP1, TSP2 . . . TSPn may be obtained to enable the comparison of a set of a plurality of semiconductor junction temperatures Tⱼ1, Tⱼ2 . . . Tⱼn to determine the actual semiconduction junction temperature of the semiconductor switching element under test. Using a greater number of independent temperature-sensitive parameters may result in a more accurate value for the semiconductor junction temperature Tⱼ.

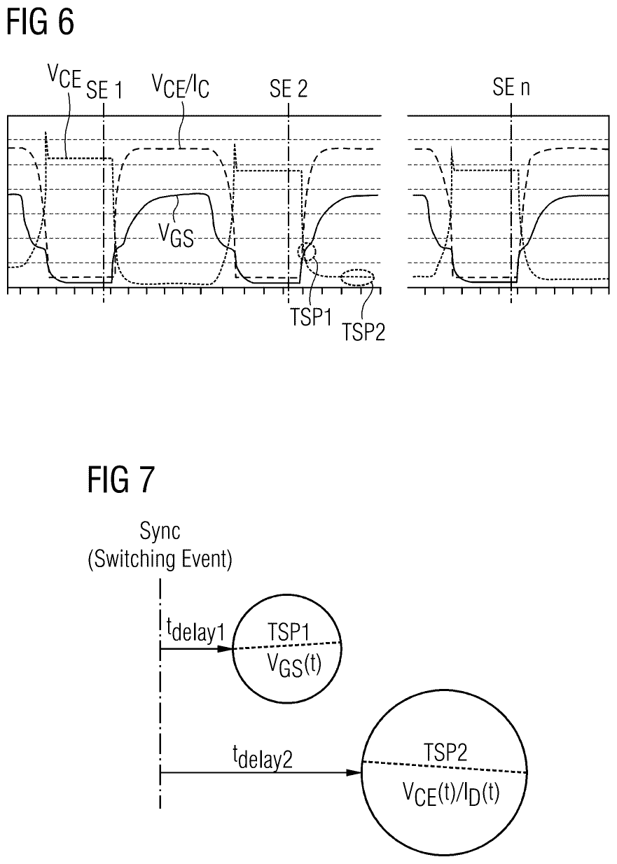

FIG. 6 is a schematic diagram showing the relationship between individual time slots and the switching event. Initially, shortly after the switching event SE1 occurs, the time slot for a first temperature-sensitive parameter, TSP1, is activated. Once this has concluded, a short while later a longer time slot for a second temperature-sensitive parameter TSP2 is activated. Once the next switching event SE2 occurs, this process is repeated, and so on. If after switching event SEn it is found that the values of the semiconduction junction temperature Tⱼ derived from the first TSP1 and second TSP2 temperature-sensitive parameters do not agree, a recalibration time slot, or a series of such slots are inserted.

FIG. 7 is a schematic illustration of measurements of the time slots highlighted in FIG. 6. The temperature-sensitive parameter TSP is measured continuously, or at high sampling rate for the duration of the time slots. Although time slots in FIGS. 6 and 7 are discrete and separated in time, time slots for different temperature-sensitive parameters may overlap.

By utilizing the switching behavior of the semiconductor switching element under test the present disclosure offers an improved method of determining the semiconductor junction temperature Tⱼ, because the behavior of the semiconductor switching element is observed under real-time conditions. Use of real-time measurements, as opposed to the external or calculated measurements of the prior art, provides that the semiconductor junction temperature Tⱼ is determined with both increased accuracy and reproducibility, resulting in a more reliable picture of the potential failure mechanisms and timings than previously available, especially at higher switching frequencies.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method of measuring a junction temperature of a semiconductor switching element in real-time, the method comprising:
taking a plurality of measurements of a first temperature-sensitive parameter of the semiconductor switching element while recording other quantities determining a semiconductor switching element operating point;
taking a plurality of measurements of at least one second temperature-sensitive parameter of the semiconductor switching element while recording other quantities determining the semiconductor switching element operating point, wherein the at least one second temperature-sensitive parameter is different from the first temperature-sensitive parameter;
calculating a first junction temperature value based on the plurality of measurements of the first temperature-sensitive parameter and calculating at least one second junction temperature value based on the plurality of measurements of the at least one second temperature-sensitive parameter; and
comparing the first calculated junction temperature value and the at least one second calculated junction temperature value to determine an actual junction temperature,
wherein each measurement of the plurality of measurements of the first temperature-sensitive parameter and the plurality of measurements of the at least one second temperature-sensitive parameter is synchronized with a switching event of the semiconductor switching element.

2. The method of claim 1, wherein the at least one second temperature-sensitive parameter is independent of the first temperature-sensitive parameter.

3. The method of claim 1, wherein the calculating of the junction temperature comprises correlating the plurality of measurements of the first temperature-sensitive parameter and correlating the plurality of measurements of the at least one second temperature-sensitive parameter to determine a single value for the first temperature-sensitive parameter and a single value for the at least one second temperature-sensitive parameter.

4. The method of claim 1, wherein the first temperature-sensitive parameter is measured in a first dedicated time slot, and
wherein the at least one second temperature-sensitive parameter is measured in a second dedicated time slot.

5. The method of claim 4, wherein the first dedicated time slot and the second dedicated time slot are each individually determined by an optimum time for measuring a temperature-sensitive parameter after the switching event occurs.

6. The method of claim 4, wherein a duration of time for the first dedicated time slot and a duration of time for the second dedicated time slot are each individually determined by a behavior of the respective temperature-sensitive parameter after the switching event occurs.

7. The method of claim 1, further comprising:
calibrating the first temperature-sensitive parameter and calibrating the at least one second temperature-sensitive parameter.

8. The method of claim 7, wherein the calibrating takes place either in a thermostatic environment separate to a real-time measurement or using additional sensors during the real-time measurement.

9. The method of claim 1, further comprising:
calibrating either the first temperature-sensitive parameter or the at least one second temperature-sensitive parameter by reference to the other temperature-sensitive parameter of the first temperature-sensitive parameter or the at least one second temperature-sensitive parameter during a real-time measurement.

10. The method of claim 1, wherein the first temperature-sensitive parameter and the at least one second temperature-sensitive parameter are determined at switching transients and each comprise a level, timing, or waveform of a gate voltage or other input pin voltage.

11. The method of claim 1, wherein the first temperature-sensitive parameter and the at least one second temperature-sensitive parameter are determined at switching transients and each comprise a level, timing, or waveform of an input current of a transistor or p-n junction type control pin device.

12. The method of claim 1, wherein the first temperature-sensitive parameter and the at least one second temperature-sensitive parameter are determined at a conduction phase of a switching operation, and each comprise a level, timing, or waveform of a drain voltage or collector voltage of semiconductor devices in a conduction period of switching.

13. The method of claim 1, wherein the first temperature-sensitive parameter and the at least one second temperature-sensitive parameter comprise characteristic switching times.

14. The method of claim 1, wherein the first temperature-sensitive parameter and the at least one second temperature-sensitive parameter are measured at operational voltage and current.

15. The method of claim 1, wherein a set of a plurality of different temperature-sensitive parameters are used to determine the junction temperature of the semiconductor switching element.

16. A device configured to measure a junction temperature of a semiconductor switching element in real-time, the device comprising:
a first data acquisition channel configured to take a plurality of measurements of a first temperature-sensitive parameter of a semiconductor switching element while recording other quantities determining a semiconductor switching element operating point;
at least one second data acquisition channel configured to take a plurality of measurements of at least one second temperature-sensitive parameter of a semiconductor switching element while recording other quantities determining the semiconductor switching element operating point, wherein the at least one second temperature-sensitive parameter is different from the first temperature-sensitive parameter; and
a processing subsystem configured to
receive inputs from the first data acquisition channel and the at least one second data acquisition channel and further inputs indicating an auxiliary temperature, current, and voltage of the semiconductor switching element;
calculate a first junction temperature value based on the plurality of measurements of the first temperature-sensitive parameter and calculate at least one second junction temperature value based on the plurality of measurements of the at least one second temperature-sensitive parameter; and
compare the first calculated junction temperature value and the at least one second calculated junction temperature value to determine an actual junction temperature,
wherein each measurement of the plurality of measurements of the first temperature-sensitive parameter and the plurality of measurements of the at least one second temperature-sensitive parameter is synchronized with a switching event of the semiconductor switching element.
